(19) United States
(12) Patent Application Publication
(10) Pub. No.: US 2022/0319926 A1
(43) Pub. Date: Oct. 6, 2022

(54) BiMOS SEMICONDUCTOR DEVICE

(71) Applicant: HONDA MOTOR CO., LTD., Tokyo (JP)

(72) Inventors: Genki NAKAMURA, Saitama (JP); Yoshinari TSUKADA, Saitama (JP); Shinya MAITA, Saitama (JP); Yasuhiro MAEDA, Saitama (JP); Yuki NEGORO, Saitama (JP)

(21) Appl. No.: 17/670,531

(22) Filed: Feb. 14, 2022

(30) Foreign Application Priority Data
Mar. 31, 2021 (JP) 2021-062251

(51) Int. Cl. H01L 21/8249; H01L 27/06; H01L 29/78

(52) U.S. Cl. CPC H01L 21/8249; H01L 27/0623; H01L 29/7813

(57) ABSTRACT

An n-channel BiMOS semiconductor device having a trench gate structure includes an n⁺ drain layer; a parallel pn layer including n⁻ drift and p pillar layers joined alternately; and a composite layer including a p base layer and an n⁺ source layer, in which the n⁺ drain layer, the parallel pn layer, and the composite layer are provided in order.

This application is based on and claims the benefit of priority from Japanese Patent Application No. 2021-062251, filed on 31 Mar. 2021, the content of which is incorporated herein by reference.

### BACKGROUND OF THE INVENTION

### Field of the Invention

The present invention relates to a BiMOS semiconductor device.

### Related Art

A BiMOS semiconductor device is known to include a bipolar transistor and a metal oxide-semiconductor field-effect transistor (MOSFET) connected in parallel on a single chip (see, for example, Patent Documents 1 and 2).

An insulated gate bipolar transistor (IGBT) is also known to be a semiconductor device including a bipolar transistor and a MOSFET combined on a single chip (see, for example, Patent Document 3).

In such a device, the MOSFET has a vertical structure for high voltage resistance and large current capacity. The vertical structure also has a trench gate structure for cell miniaturization and low on-resistance.
Patent Document 1: Japanese Unexamined Patent Application, Publication No. S61-180472
Patent Document 2: Japanese Unexamined Patent Application, Publication No. S61-225854
Patent Document 3: Japanese Unexamined Patent Application, Publication No. S60-196974

### SUMMARY OF THE INVENTION

FIG. 1 shows a conventional n-channel BiMOS semiconductor device having a trench gate structure.

The BiMOS semiconductor device 10 includes a collector/drain electrode 11, and an n⁺ drain layer 12, an n-drift layer 13, and a composite layer 14 including a p base layer 14a and an n⁺ source layer 14b, which are provided in order on the collector/drain electrode 11. The BiMOS semiconductor device 10 has a trench 15, which extends from the surface of the composite layer 14 to a top portion of the n⁻ drift layer 13, and further includes a gate insulating film 16 and a gate electrode 17 which is provided inside the trench 15 with the gate insulating film 16 disposed between the gate electrode 17 and the wall of the trench 15. In this structure, the n⁺ source layer 14b is provided in an upper portion of the composite layer 14 and on each of the two sides of the trench 15. The BiMOS semiconductor device 10 further includes an emitter/source electrode 18 on the n⁺ source layer 14b and includes a base electrode 19 that is spaced apart by a given distance from the emitter/source electrode 18 and provided on an n⁺ source layer 14b-free region of the composite layer 14.

In FIG. 1, a half cell is indicated by broken lines. Such a half cell is shown in FIG. 2 and other drawings for illustrating the BiMOS semiconductor device.

Next, how the BiMOS semiconductor device 10 operates will be explained with reference to FIG. 2. It should be noted that in FIG. 2, the thick lines representing electron and hall currents indicate that the currents are large while the thin lines representing electron and hall currents indicate that the currents are small.

As shown in FIG. 2, an inversion layer 14c is generated in a portion of the p base layer 14a in the vicinity of the gate electrode 17 when a gate voltage positive with respect to the emitter/source electrode 18 is applied to the gate electrode 17 while a voltage positive with respect to the emitter/source electrode 18 is applied to the collector/drain electrode 11. In this state, an electron current 21a flows from the collector/drain electrode 11 to the emitter/source electrode 18 through the n⁺ drain layer 12, the n⁻ drift layer 13, the inversion layer 14c, and the n⁺ source layer 14b. When a base current is allowed to flow to the base electrode 19 while a voltage positive with respect to the emitter/source electrode 18 is applied to the collector/drain electrode 11, electron currents 21b and 21c flow and an electron current 21d flows from the collector/drain electrode 11 to the emitter/source electrode 18 through the n⁺ drain layer 12, the n⁻ drift layer 13, the p base layer 14a, and the n⁺ source layer 14b. A hall current 22 also flows from the p base layer 14a to the n⁻ drift layer 13. In this state, the electron currents 21b and 21c flow into the n⁺ source layer 14b from the lateral and lower sides, respectively.

Unfortunately, the BiMOS semiconductor device 10 has a problem in that, for the purpose of high voltage resistance, the n⁻ drift layer 13 cannot have a high impurity concentration and thus a low current density is provided, because the depletion layer extending in the n⁻ drift layer 13 has the highest field intensity at the interface with the p base layer 14a.

FIG. 3 shows a conventional n-channel IGBT having a trench gate structure.

The IGBT 10A includes a collector electrode 11, and a p⁺ collector layer 12A, an n⁺ collector layer 12, an n⁻ drift layer 13, and a composite layer 14 including a p emitter layer 14a and an n⁺ emitter layer 14b, which are provided in order on the collector electrode 11. The IGBT 10A has a trench 15, which extends from the surface of the composite layer 14 to a top portion of the n⁻ drift layer 13, and further includes a gate insulating film 16 and a gate electrode 17 which is provided inside the trench 15 with the gate insulating film 16 disposed between the gate electrode 17 and the wall of the trench 15. In this structure, the n⁺ emitter layer 14b is provided on each of the two sides of the trench 15 at an upper portion of the composite layer 14. The IGBT 10A further includes an emitter electrode 18A on the top of the composite layer 14.

Unfortunately, the IGBT 10A has a problem in that a built-in voltage of about 0.6 V may increase the on-voltage.

It is an object of the present invention to provide a BiMOS semiconductor device having an improved current density.

An aspect of the present invention is directed to an n-channel BiMOS semiconductor device having a trench gate structure, the n-channel BiMOS semiconductor device including: an n⁺ drain layer; a parallel pn layer including n⁻ drift and p pillar layers joined alternately; and a composite layer including a p base layer and an n⁺ source layer, the n⁺ drain layer, the parallel pn layer, and the composite layer being provided in order.

The BiMOS semiconductor device may further have a portion increased in resistance between the p pillar layer and the p base layer.

The BiMOS semiconductor device may further have a portion increased in resistance between a portion of the p base layer above the p pillar layer and the n⁺ source layer.

Another aspect of the present invention is directed to a p-channel BiMOS semiconductor device having a trench gate structure, the p-channel BiMOS semiconductor device including: a p⁺ drain layer; a parallel pn layer including p⁻ drift and n pillar layers joined alternately; and a composite layer including an n base layer and a p⁺ source layer, the p⁺ drain layer, the parallel pn layer, and the composite layer being provided in order.

The present invention makes it possible to provide a BiMOS semiconductor device having an improved current density.

### BRIEF DESCRIPTION OF THE DRAWINGS

FIG. 1 is a cross-sectional view showing a conventional n-channel BiMOS semiconductor device having a trench gate structure;

FIG. 2 is a view for illustrating how the BiMOS semiconductor device of FIG. 1 operates;

FIG. 3 is a cross-sectional view showing a conventional n-channel IGBT having a trench gate structure;

FIG. 4 is a cross-sectional view showing an example of a BiMOS semiconductor device according to an embodiment of the present invention;

FIG. 5 is a view for illustrating how the BiMOS semiconductor device of FIG. 4 operates;

FIG. 6 is a graph showing the results of simulation of the I-V curves of the BiMOS semiconductor devices of FIGS. 1 and 4 and the IGBT of FIG. 3;

FIG. 7 is a view showing a modified example of the BiMOS semiconductor device of FIG. 4;

FIGS. 8A and 8B are views showing the results of simulation of electron current vectors in the BiMOS semiconductor devices of FIGS. 4 and 7;

FIG. 9 is a view showing another modified example of the BiMOS semiconductor device of FIG. 4;

FIGS. 10A and 10B are views showing the results of simulation of electron current vectors in the BiMOS semiconductor devices of FIGS. 7 and 9;

FIG. 11 is a graph showing the results of simulation of the I-V curves of the BiMOS semiconductor devices of FIGS. 7 and 9;

FIGS. 12A and 12B are views showing the results of simulation of electron current vectors and hall current vectors in the BiMOS semiconductor device of FIG. 9;

FIGS. 13A and 13B are graphs showing the results of simulation of the carrier density at the A-A′ cross-section in FIG. 12A;

FIG. 14 is a graph showing the results of simulation of the potential barrier at the A-A′ cross-section in FIG. 12A;

FIG. 15 is a view for illustrating a complementary method for operating only the MOSFET part in the BiMOS semiconductor device of FIG. 9;

FIG. 16 is a view for illustrating a complementary method for operating only the bipolar transistor part in the BiMOS semiconductor device of FIG. 9;

FIG. 17 is a timing chart for illustrating an exemplary way to operate the MOSFET part and the bipolar transistor part independently in the BiMOS semiconductor device of FIG. 9;

FIG. 18 is a view for illustrating other exemplary ways to operate the MOSFET part and the bipolar transistor part independently in the BiMOS semiconductor device of FIG. 9; and

FIG. 19 is a cross-sectional view showing another example of the BiMOS semiconductor device according to the embodiment.

### DETAILED DESCRIPTION OF THE INVENTION

Hereinafter, embodiments of the present invention will be described with reference to the drawings.

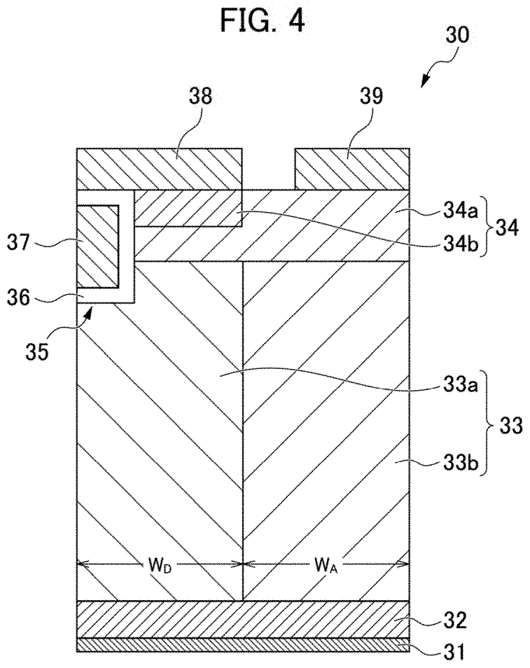

FIG. 4 shows an exemplary BiMOS semiconductor device according to an embodiment of the present invention.

The BiMOS semiconductor device 30 is an n-channel BiMOS semiconductor device having a trench gate structure.

The BiMOS semiconductor device 30 includes a collector/drain electrode 31, an n⁺ drain layer 32, a parallel pn layer 33 including an n⁻ drift layer 33a and a p pillar layer 33b joined alternately, and a composite layer 34 including a p base layer 34a and an n⁺ source layer 34b, in which the n⁺ drain layer 32, the parallel pn layer 33, and the composite layer 34 are provided in order on the collector/drain electrode 31. The BiMOS semiconductor device 30 has a trench 35 extending from the surface of the composite layer 34 to a top portion of the parallel pn layer 33, and further includes a gate insulating film 36 and a gate electrode 37 that is provided inside the trench 35 with the gate insulating film 36 disposed between the gate electrode 37 and the wall of the trench 35. In this structure, the n⁺ source layer 34b is provided in an upper portion of the composite layer 34 and on each of the two sides of the trench 35 and provided above the n⁻ drift layer 33a. The BiMOS semiconductor device 30 further includes an emitter/source electrode 38 on the n⁺ source layer 34b and includes a base electrode 39 that is spaced apart by a given distance from the emitter/source electrode 38 and provided on an n⁺ source layer 34b-free region of the composite layer 34.

In the BiMOS semiconductor device 30, the parallel pn layer 33 allows the depletion layer extending in the n⁻ drift layer 33a to have an almost uniform field intensity in the thickness direction and thus allows the n⁻ drift layer 33a to have a high impurity concentration, which allows the BiMOS semiconductor device 30 to have an improved current density.

In this case, the impurity concentration N_{D} of the n⁻ drift layer 33a and the impurity concentration N_{A} of the p pillar layer 33b satisfy the formula:

N_{D}=N_{A}

The width W_{D} of the n⁻ drift layer 33a and the width W_{A} of the p pillar layer 33b also satisfy the formula:

W_{D}=W_{A}

The substrate material for the BiMOS semiconductor device 30 is typically, but not limited to, Si, SiC, GaN, Ga₂O₃, or any other semiconductor material. The impurities may be a known acceptor and a known donor.

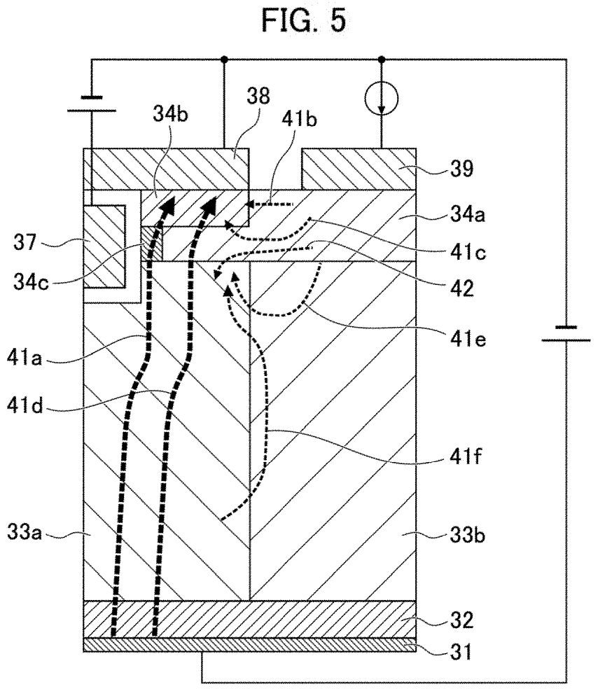

Next, how the BiMOS semiconductor device 30 operates will be explained with reference to FIG. 5. It should be noted that in FIG. 5, the thick lines representing electron and hall currents indicate that the currents are large while the thin lines representing electron and hall currents indicate that the currents are small.

As shown in FIG. 5, an inversion layer 34c is generated in a portion of the p base layer 34a in the vicinity of the gate electrode 37 when a gate voltage positive with respect to the emitter/source electrode 38 is applied to the gate electrode 37 while a voltage positive with respect to the emitter/source electrode 38 is applied to the collector/drain electrode 31. In this state, an electron current 41a flows from the collector/drain electrode 31 to the emitter/source electrode 38 through the n⁺ drain layer 32, the n⁻ drift layer 33a, the inversion layer 34c, and the n⁺ source layer 34b. When a base current is allowed to flow to the base electrode 39 while a voltage positive with respect to the emitter/source electrode 38 is applied to the collector/drain electrode 31, electron currents 41b and 41c flow from the p base layer 34a to the n⁺ source layer 34b. An electron current 41d also flows from the collector/drain electrode 31 to the emitter/source electrode 38 through the n⁺ drain layer 32, the n⁻ drift layer 33a, the p base layer 34a, and the n⁺ source layer 34b. A hall current 42 also flows from the p base layer 34a to the n⁻ drift layer 33a. In this case, the electron currents 41b and 41c flow into the n⁺ source layer 34b from the lateral side and the lower side, respectively.

In this state, as a base current (hall current 42) flows from the p base layer 34a to the n⁻ drift layer 33a, an electron current 41e flows from the p base layer 34a to the n⁻ drift layer 33a through the p pillar layer 33b. An electron current 41f also flows from a part of the n⁻ drift layer 33a to another part of the n⁻ drift layer 33a through the p pillar layer 33b.

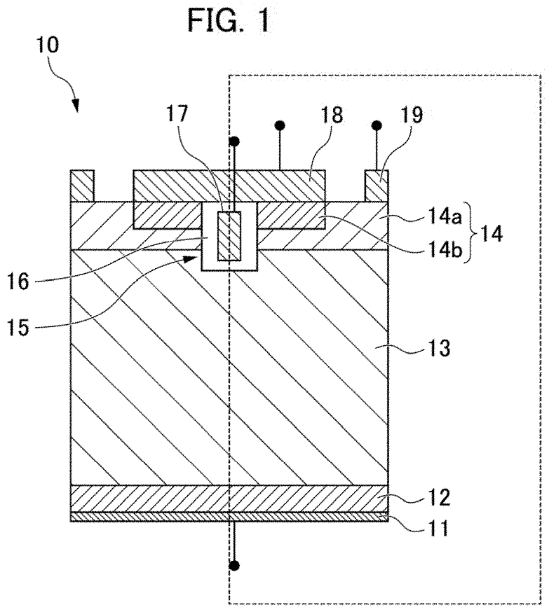

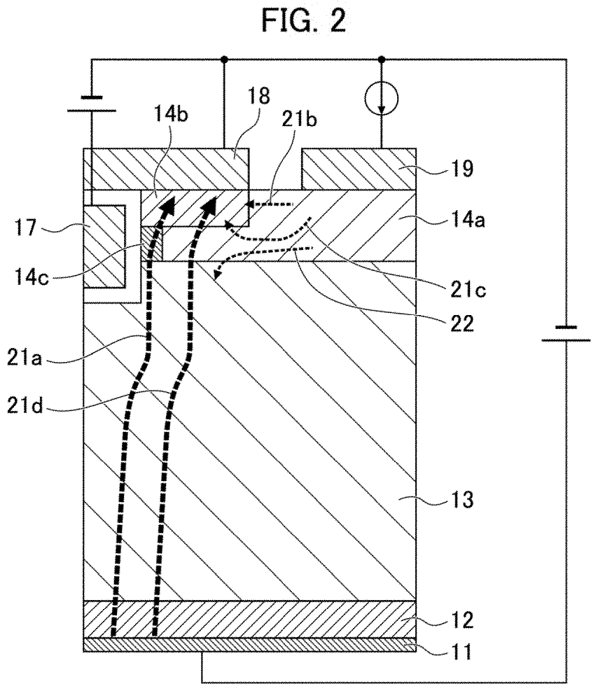

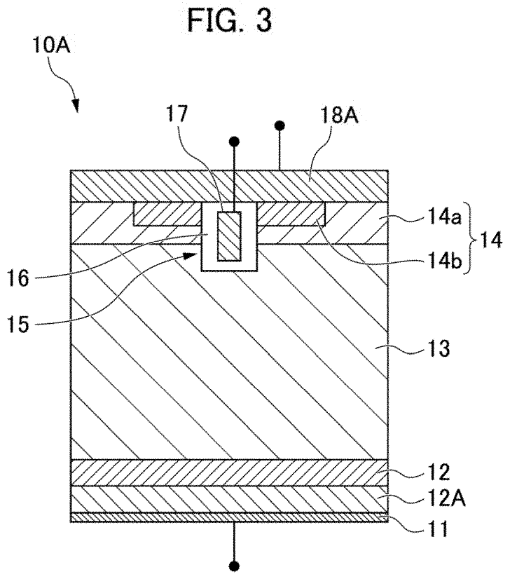

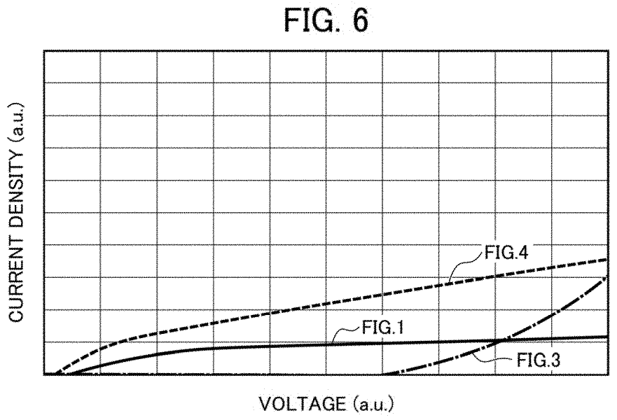

FIG. 6 shows the results of simulation of the I-V curves of the BiMOS semiconductor devices 10 and 30 (see FIGS. 1 and 4) and the IGBT 10A (see FIG. 3).

FIG. 6 indicates that the BiMOS semiconductor device 30 has a current density higher than that of the BiMOS semiconductor device 10 or the IGBT 10A.

In FIG. 6, the I-V curves are the results of the simulation, in which the voltage is applied to the collector/drain electrode 31, and the current density is the density of the current flowing to the collector/drain electrode 31.

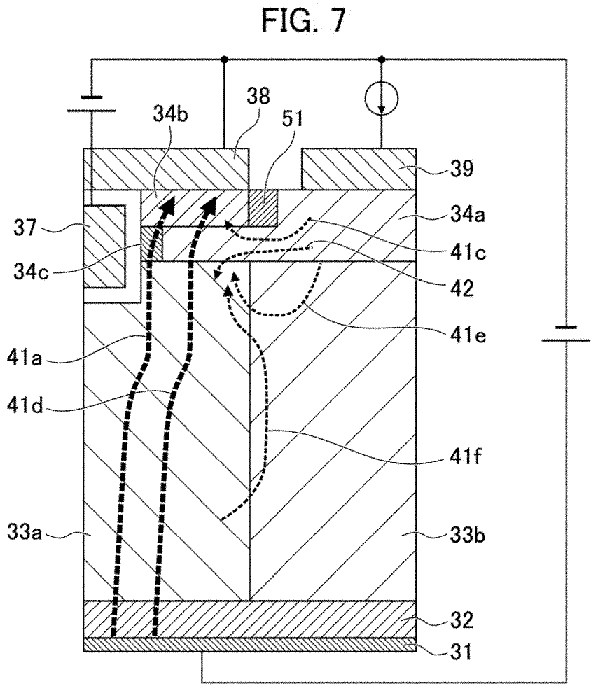

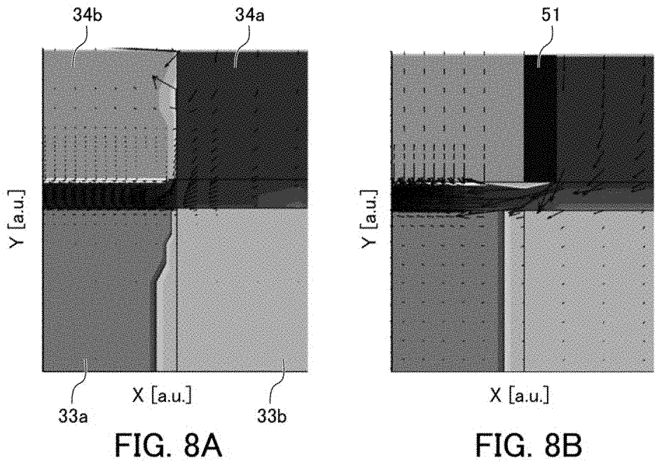

As shown in FIG. 7, the BiMOS semiconductor device 30 may further include a high-resistance layer 51 provided between a portion of the p base layer 34a above the p pillar layer 33b and the n⁺ source layer 34b. As compared to the case (see FIG. BA) where the high-resistance layer 51 is not provided as shown in FIG. 4, the high-resistance layer 51 provided as shown in FIG. 7 can reduce the electron current 41b (see FIG. 8B) flowing from the lateral side to the n⁺ source layer 34b (see FIG. 5) when the base current is allowed to flow to the base electrode 39, so that the BiMOS semiconductor device 30 can have an improved current density.

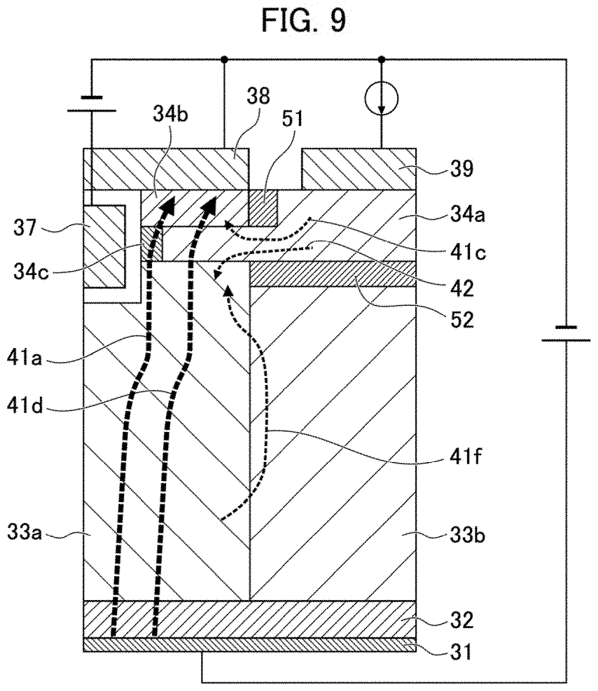

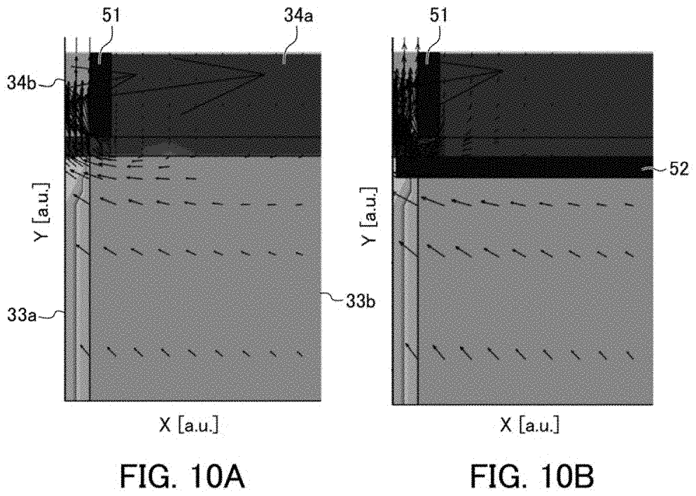

As shown in FIG. 9, the BiMOS semiconductor device 30 may further include a high-resistance layer 52 provided between the p pillar layer 33b and the p base layer 34a. As compared to the case (see FIG. 10A) where the high-resistance layer 52 is not provided as shown in FIG. 7, the high-resistance layer 52 provided as shown in FIG. 9 can reduce the electron current 41e (see FIG. 10B) flowing from the p base layer 34a to the n-drift layer 33a through the p pillar layer 33b (see FIG. 5), so that the BiMOS semiconductor device 30 can have an improved current density.

Alternatively, the high-resistance layer 51 may be omitted from between a portion of the p base layer 34a above the p pillar layer 33b and the n⁺ source layer 34b in the structure shown in FIG. 9.

The high-resistance layers 51 and 52 may be made of SiO₂ as a non-limiting example. The high-resistance layers 51 and 52 are a mode for increasing the resistance of the interlayer portion. Alternatively, high-resistance films may be used in place of the SiO₂ films or other insulating films. Other methods for increasing the resistance of the interlayer portion may be, but not limited to, spatial isolation between the layers.

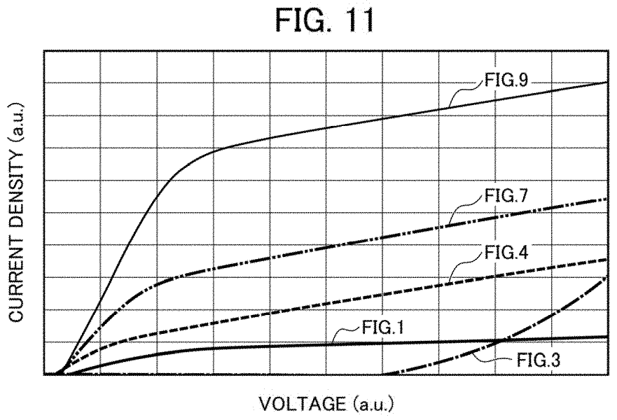

FIG. 11 shows the results of simulation of the I-V curves of the BiMOS semiconductor devices of FIGS. 7 and 9. FIG. 11 also shows the results shown in FIG. 6.

FIG. 11 indicates that the BiMOS semiconductor devices of FIGS. 7 and 9 each have a current density higher than that of the BiMOS semiconductor device 30 (see FIG. 4).

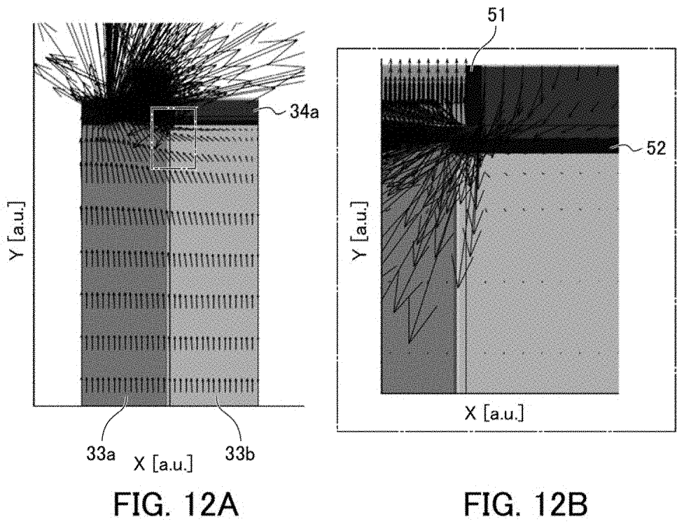

FIGS. 12A and 12B show the results of simulation of electron current vectors (see FIG. 12A) and hall current vectors (see FIG. 12B) in the BiMOS semiconductor device of FIG. 9.

As shown in FIG. 12B, the hall current 42 (see FIG. 9) flows from the p base layer 34a to the n⁻ drift layer 33a and also partially flows into the p pillar layer 33b. This results in positive charging of the p pillar layer 33b to decrease the potential barrier, so that the electron current 41f (see FIG. 9) flows from the n⁻ drift layer 33a to the p pillar layer 33b. After flowing in the p pillar layer 33b, the electron current 41f further flows into the n⁻ drift layer 33a as shown in FIG. 12A.

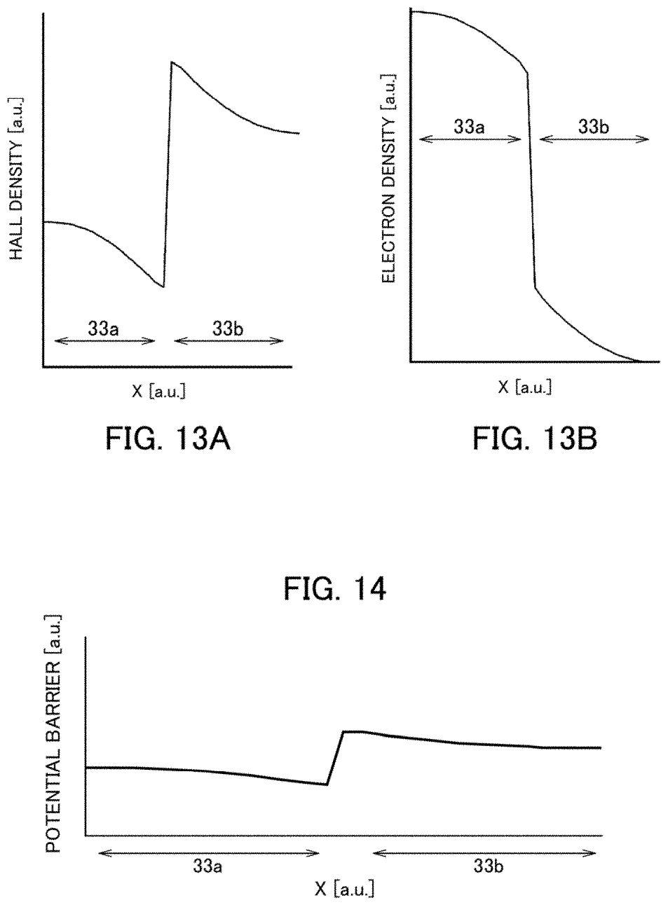

FIGS. 13A and 13B show the results of simulation of the carrier density at the A-A′ cross-section in FIG. 12A. FIGS. 13A and 13B show the hall density and the electron density, respectively.

FIG. 13A indicates that the hall density at the interface between the p pillar layer 33b and the n⁻ drift layer 33a increases to about 15 times the initial density prior to the start of the base current flow.

FIG. 13B indicates that the electron density at the interface between the p pillar layer 33b and the n⁻ drift layer 33a increases to about 45 times the initial density prior to the start of the base current flow so that charge balance is achieved.

FIG. 14 shows the results of simulation of the potential barrier at the A-A′ cross-section in FIG. 12A.

FIG. 14 indicates that the potential barrier at the interface between the n⁻ drift layer 33a and the p pillar layer 33b decreases to about 1/400 of the initial value prior to the start of the base current flow.

Accordingly, the potential barrier at the interface between the n⁻ drift layer 33a and the p pillar layer 33b in the BiMOS semiconductor device of FIG. 9 decreases to allow the electron current 41f to easily flow from the n⁻ drift layer 33a to the p pillar layer 33b, so that the p pillar layer 33b is more effectively utilized as a route for the electron current 41f.

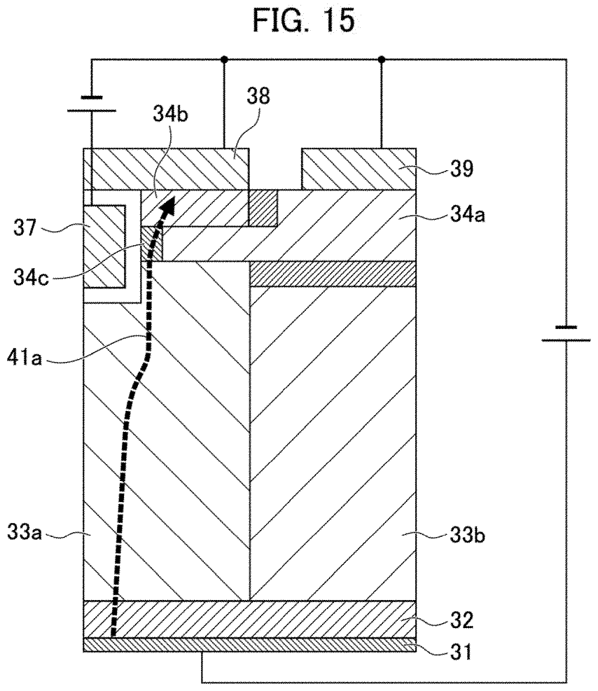

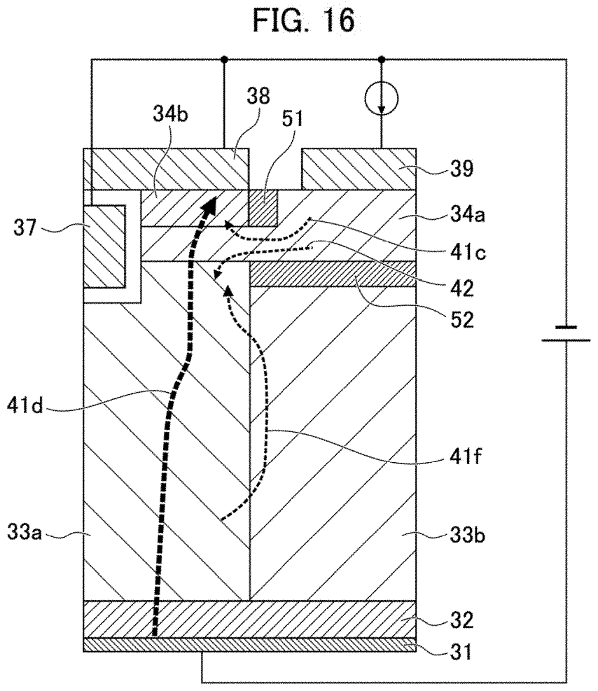

In the BiMOS semiconductor device of FIG. 9, only the MOSFET part can be operated by voltage-only driving (see FIG. 15), and only the bipolar transistor part can be operated by current-only driving (see FIG. 16).

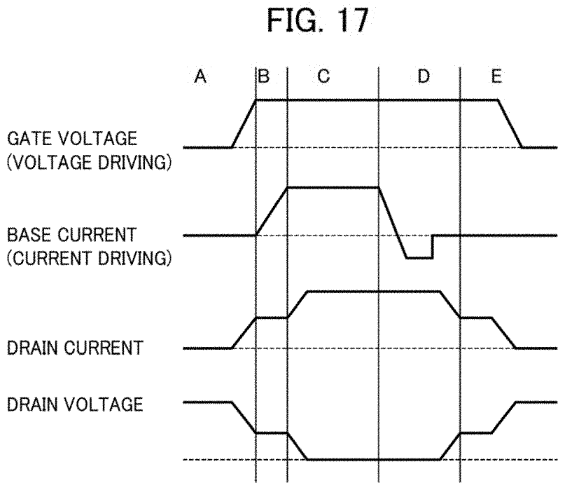

FIG. 17 shows an exemplary way to operate the MOSFET part and the bipolar transistor part independently in the BiMOS semiconductor device of FIG. 9.

First, at timing A, the gate voltage is switched from Low (L) to High (H) to turn on the MOSFET so that the drain current increases while the drain voltage decreases. Next, at timing B, the base current is switched from L to H to turn on the bipolar transistor, so that at timing C, the drain current increases while the drain voltage decreases. Next, at timing D, the base current is switched from H to L to turn off the bipolar transistor, so that after the elapse of a given period of time, the drain current decreases while the drain voltage increase. Next, at timing E, the gate voltage is switched from H to L to turn off the MOSFET so that the drain current decreases while the drain voltage increases, which results in return to the initial state.

In this case, the bipolar transistor has secondary breakdown limitation in the safe operating area. It is preferred therefore that as shown in FIG. 17, turning off the bipolar transistor should be followed by turning off the MOSFET taking into account bipolar transistor operation delay.

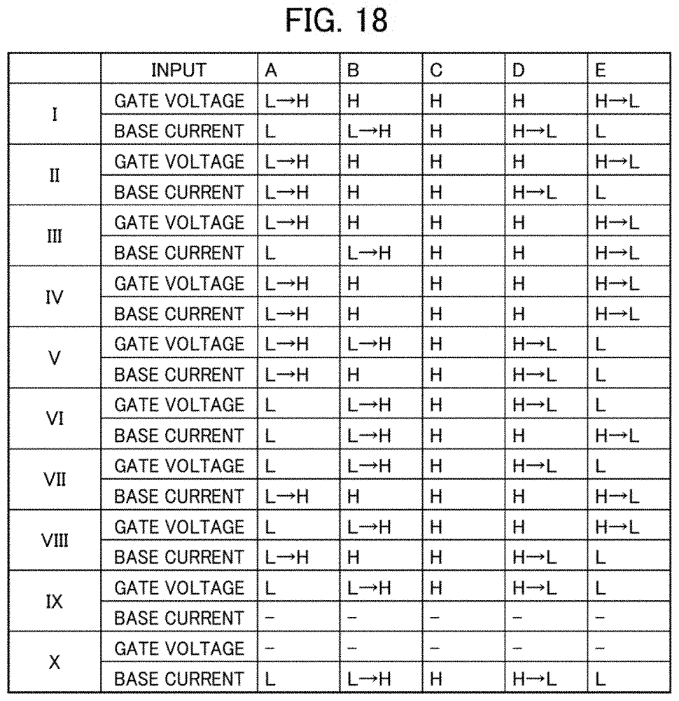

FIG. 18 shows other exemplary ways to operate the MOSFET part and the bipolar transistor part independently in the BiMOS semiconductor device of FIG. 9. In FIG. 18, I represents the method shown in FIG. 17.

While the BiMOS semiconductor device according to the embodiment has been described with reference to an n-channel BiMOS semiconductor device, the BiMOS semiconductor device according to the embodiment is not limited to an n-channel type and may also be a p channel type.

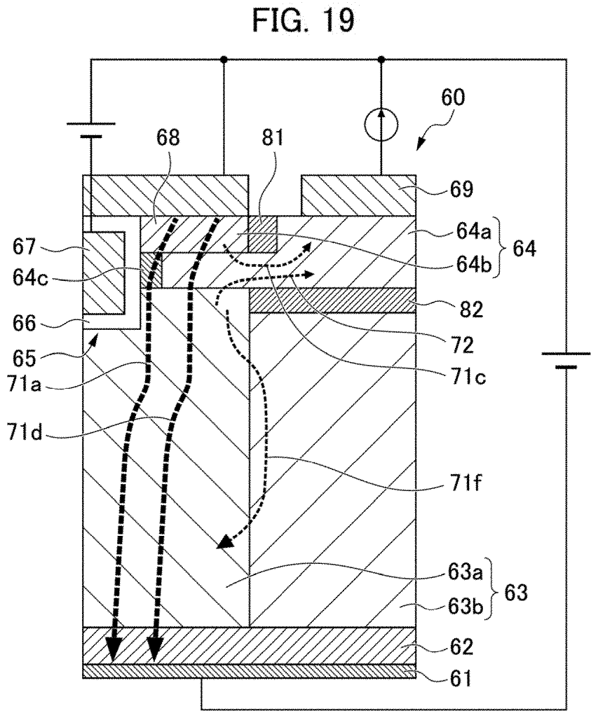

FIG. 19 shows another exemplary BiMOS semiconductor device according to the embodiment.

The BiMOS semiconductor device 60 is a p-channel BiMOS semiconductor device having a trench gate structure.

The BiMOS semiconductor device 60 includes a collector/drain electrode 61, a p⁺ drain layer 62, a parallel pn layer 63 including a p⁻ drift layer 63a and an n pillar layer 63b joined alternately, and a composite layer 64 including an n base layer 64a and a p⁺ source layer 64b, in which the p⁺ drain layer 62, the parallel pn layer 63, and the composite layer 64 are provided in order on the collector/drain electrode 61. The BiMOS semiconductor device 60 has a trench 65 extending from the surface of the composite layer 64 to a top portion of the parallel pn layer 63, and further includes a gate insulating film 66 and a gate electrode 67 that is provided inside the trench 65 with the gate insulating film 66 disposed between the gate electrode 67 and the wall of the trench 65. In this structure, the p⁺ source layer 64b is provided in an upper portion of the composite layer 64 and on each of the two sides of the trench 65 and provided above the p⁻ drift layer 63a. The BiMOS semiconductor device 60 further includes an emitter/source electrode 68 on the p⁺ source layer 64b and includes a base electrode 69 that is spaced apart by a given distance from the emitter/source electrode 68 and provided on a p⁺ source layer 64b-free region of the composite layer 64.

In the BiMOS semiconductor device 60, the parallel pn layer 63 allows the depletion layer extending in the p⁻ drift layer 63a to have an almost uniform field intensity in the thickness direction and thus allows the p⁻ drift layer 63a to have a high impurity concentration, which allows the BiMOS semiconductor device 60 to have an improved current density.

The BiMOS semiconductor device 60 further includes a high-resistance layer 81 provided between a portion of the n base layer 64a above the n pillar layer 63b and the p⁺ source layer 64b, and includes a high-resistance layer 82 provided between the n pillar layer 63b and the n base layer 64a.

The high-resistance layers 81 and 82 may be made of SiOx as a non-limiting example. The high-resistance layers 81 and 82 are a mode for increasing the resistance of the interlayer portion. Alternatively, high-resistance films may be used in place of the SiO₂ films or other insulating films. Other methods for increasing the resistance of the interlayer portion may be, but not limited to, spatial isolation between the layers.

At least one of the high-resistance layers 81 and 82 may be omitted.

In this case, the impurity concentration N_{A} of the p⁺ drift layer 63a and the impurity concentration N₀ of the n pillar layer 63b satisfy the formula:

N_{D}=N_{A}

The width W_{A} of the p⁻ drift layer 63a and the width W_{D} of the n pillar layer 63b also satisfy the formula:

W_{A}=W_{D}

The substrate material for the BiMOS semiconductor device 60 is typically, but not limited to, Si, SiC, GaN, Ga₂O₃, or any other semiconductor material. The impurities may be a known acceptor and a known donor.

Next, how the BiMOS semiconductor device 60 operates will be explained. It should be noted that in FIG. 19, the thick lines representing electron and hall currents indicate that the currents are large while the thin lines representing electron and hall currents indicate that the currents are small.

As shown in FIG. 19, an inversion layer 64c is generated in a portion of the n base layer 64a in the vicinity of the gate electrode 67 when a gate voltage negative with respect to the emitter/source electrode 68 is applied to the gate electrode 67 while a voltage negative with respect to the emitter/source electrode 68 is applied to the collector/drain electrode 61. In this state, a hall current 71a flows from the emitter/source electrode 68 to the collector/drain electrode 61 through the p⁺ drain layer 62, the p⁻ drift layer 63a, the inversion layer 64c, and the p⁺ source layer 64b. When a base current is allowed to flow from the base electrode 69 while a voltage negative with respect to the emitter/source electrode 68 is applied to the collector/drain electrode 61, a hall current 71c flows from the p⁺ source layer 64b to the n base layer 64a. A hall current 71d also flows from the emitter/source electrode 68 to the collector/drain electrode 61 through the p⁺ drain layer 62, the p⁻ drift layer 63a, the n base layer 64a, and the p⁺ source layer 64b. An electron current 72 also flows from the p⁻ drift layer 63a to the n base layer 64a. In this state, the hall current 71c flows into the n base layer 64a from the lower side.

In this state, a hall current 71f flows from a part of the p⁻ drift layer 63a to another part of the p⁻ drift layer 63a through the n pillar layer 63b.

### EXPLANATION OF REFERENCE NUMERALS

10: BiMOS semiconductor device
10A: IGBT
11: Collector/drain electrode (collector electrode)
12: n⁺ drain layer (n⁺ collector layer)
12A: p⁺ collector layer
13: n⁻ drift layer
14: Composite layer
14a: p base layer (p emitter layer)
14b: n⁺ source layer (n⁺ emitter layer)
14c: Inversion layer
15: Trench
16: Gate insulating film
17: Gate electrode
18: Emitter/source electrode
18A: Emitter electrode
19: Base electrode
21a, 21b, 21c, 21d: Electron current
22: Hall current
30: BiMOS semiconductor device
31: Collector/drain electrode
32: n⁺ drain layer
33: Parallel pn layer
33a: n⁻ drift layer
33b: p pillar layer
34: Composite layer
34a: p base layer
34b: n⁺ source layer
34c: Inversion layer
35: Trench
36: Gate insulating film
37: Gate electrode
38: Emitter/source electrode
39: Base electrode
41a, 41b, 41c, 41d, 41e, 41f: Electron current
42: Hall current
51, 52: High-resistance layer
60: BiMOS semiconductor device
61: Collector/drain electrode
62: p⁺ drain layer
63: Parallel pn layer
63a: p⁻ drift layer
63b: n pillar layer
64: Composite layer
64a: n base layer
64b: p⁺ source layer
64c: Inversion layer
65: Trench
66: Gate insulating film
67: Gate electrode
68: Emitter/source electrode
69: Base electrode
71a, 71c, 71d, 71f: Hall current
72: Electron current
81, 82: High-resistance layer

What is claimed is:

1. An n-channel BiMOS semiconductor device having a trench gate structure, the n-channel BiMOS semiconductor device comprising:
an n⁺ drain layer;
a parallel pn layer comprising n⁻ drift and p pillar layers joined alternately; and
a composite layer comprising a p base layer and an n⁺ source layer, the n⁺ drain layer, the parallel pn layer, and the composite layer being provided in order.

2. The BiMOS semiconductor device according to claim 1, further comprising a portion increased in resistance between a portion of the p base layer above the p pillar layer and the n⁺ source layer.

3. The BiMOS semiconductor device according to claim 1, further comprising a portion increased in resistance between the p pillar layer and the p base layer.

4. A p-channel BiMOS semiconductor device having a trench gate structure, the p-channel BiMOS semiconductor device comprising:
a p⁺ drain layer;
a parallel pn layer comprising p⁻ drift and n pillar layers joined alternately; and
a composite layer comprising an n base layer and a p⁺ source layer, the p⁺ drain layer, the parallel pn layer, and the composite layer being provided in order.
